(19) United States
(12) Patent Application Publication
(10) Pub. No.: US 2026/0331444 A1
(43) Pub. Date: Oct. 22, 2026

(54) System and method for igniting a plasma

(71) Applicant: VitalFluid B.V., Eindhoven (NL)

(72) Inventors: Pieter Polo Van Ooij, Eindhoven (NL); Maxime Frédéric Gendre, Eindhoven (NL); Frank Jozef Cornelis Marie Beckers, Eindhoven (NL)

(73) Assignee: VitalFluid B.V., Eindhoven (NL)

(21) Appl. No.: 19/481,542

(22) PCT Filed: May 8, 2024
(86) PCT No.: PCT/EP2024/062849

§ 371 Date: Nov. 5, 2025

(30) Foreign Application Priority Data
May 12, 2023 (NL) 2034816

(51) Int. Cl. H01J 37/32

(52) U.S. Cl. CPC H01J 37/32834; H01J 37/32018

(57) ABSTRACT

The invention relates to a system and method for operating an atmospheric or super-atmospheric plasma, the system comprising:
a plasma reactor
an electric field generator configured to generate an electric field in the plasma reactor, said electric field generator having an electric field generation limit;
characterized by:
a pump configured to remove gas from the plasma reactor;
a control unit;
wherein the control unit is configured to
   lower the pressure in the plasma reactor using the pump until a first pressure is reached;
   subsequently or simultaneously applying the electric field in the plasma reactor until a plasma ignites in the plasma reactor;
   after ignition, letting the pressure in the plasma reactor increase at a rate so that the electric field generator continuously operates within the electric field generation limit until a second pressure is reached;
   operating the plasma at the second pressure.

### FIELD OF THE INVENTION

The invention relates to a system and method for igniting a plasma. Such plasma may be used for processing a fluid. Examples of such plasma activated fluid processing include plasma activated water synthesis and processing gas comprising nitrogen and oxygen, such as air, for nitrogen fixation.

### BACKGROUND OF THE INVENTION

Water can be “activated” by applying an atmospheric plasma in contact with the water, for instance by creating plasma inside (bubbles in) the water, or along a water surface. Plasma activated water (PAW) typically contains hydrogen peroxide, nitrates, nitrites, where peroxynitrite is formed due to a reaction with nitrite and hydrogen peroxide in an acidic environment, and is present in PAW for period of approximately 15 minutes after activation. Further, PAW typically has a pH ranging from 0 to 7. The components of PAW and the low pH have proven synergistic antimicrobial effects against bacteria, biofilms, yeasts and other microorganisms. PAW can be used as a natural fertilizer, it enhances seed germination and stimulates plant growth.

The production of nitrate as a result of the activation process is shown to be very energy efficient and can be used as an energy efficient alternative for the production of nitrogen components in fertilizers, currently produced by the high energy consuming Haber-Bosch process. The activation process has also shown to be efficient for the production of hydrogen peroxide.

Nitrogen fixation (NF) is a process by which nitrogen molecules (N₂) in air or nitrogen gas, which are relatively nonreactive molecules, are converted into nitrogenous compounds. A plasma in air can create reactive nitrogen and oxygen species which form nitric and nitrous acid in an aqueous environment.

The Birkeland-Eyde electric arc nitrogen fixation process was developed in 1903. The process consists of multiple steps. First an arc plasma is applied to convert nitrogen/oxygen into nitric oxide (NO) which is subsequently further oxidized into nitric dioxide (NO₂) by cooling the hot gasses and mixing them with atmospheric oxygen, finally NO₂ is converted into nitric acid (HNO₃) by absorption in water.

In the context of this description, the term “nitrogen fixation” shall refer to the formation of any nitrogen compound except N₂.

Plasma activated fluid processing can be achieved with a thermal or non-thermal plasma, which can be generated by connecting an alternating current (AC) or direct current (DC) power source to a circuit comprising a reaction electrode (sometimes referred to as a high-voltage (HV) electrode) and a ground electrode, between which the plasma will be created. The electrodes are located inside a reaction chamber which typically has inlets and outlets for fluid to be processed.

In the case of PAW synthesis, there will be inlets and outlets for water and air, in the case of NF, inlets and outlets for gas can be sufficient.

A problem with current plasma activated fluid processing devices for PAW and/or NF is to reliably ignite the atmospheric or higher pressure plasma. The voltage required to ignite a plasma device is typically higher than its operating voltage. A more general way of stating this is that the electrical field strength required to ignite a plasma device is higher than the electrical field strength needed to sustain the plasma after ignition. Where this application makes a statement about voltage, unless the context demands otherwise, the same statement applies to electric field strength.

The difference between those voltages/electric field strengths usually increases at higher fill pressures and at longer electrode distances, which poses a technological challenge as the power supply has to deliver a higher open-circuit voltage (OCV) and the circuit connecting it to the plasma device has to be designed to withstand the electrical stress. Both factors result in a more complex system, which has a negative impact on both cost and reliability.

Japanese patent publication JP4590528 discloses a glow plasma generation device and method that can generate glow plasma in a gaseous phase in contact with a liquid phase, where the liquid and atmospheric gas are mixed. The device includes a storage part made of dielectric material that can store the liquid and atmospheric gas, a gas atmosphere creation device to maintain the presence of atmospheric gas in the storage part, a rod-shaped internal electrode within the storage part, and a plate-shaped external electrode arranged on the outer peripheral wall of the storage part at varying distances from the internal electrode.

The present invention strives to provide an improved system and method for igniting and operating a plasma.

### SUMMARY OF THE INVENTION

According to a first aspect, the invention provides a system for operating an atmospheric or super-atmospheric plasma, the system comprising
a plasma reactor
an electric field generator configured to generate an electric field in the plasma reactor, said electric field generator having an electric field generation limit;
characterized by:
a pump configured to remove gas from the plasma reactor;
a control unit;
wherein the control unit is configured to
   lower the pressure in the plasma reactor using the pump until a first pressure is reached;
   subsequently or simultaneously applying the electric field in the plasma reactor until a plasma ignites in the plasma reactor;
   after ignition, letting the pressure in the plasma reactor increase at a rate so that the electric field generator continuously operates within the electric field generation limit until a second pressure is reached;
   operating the plasma at the second pressure.

The electric field generator can be a high voltage source, or other means for generating an electric field that can be used to ignite a plasma. The electric field generator will have an electric field limit, which can e.g. be specified by the generator's manufacturer or which can be obtained experimentally or calculated from parameters of the electric field generator. The theory and experiments described in this disclosure allow a skilled person to do the necessary routine experiments to implement the functional feature “letting the pressure in the plasma reactor increase at a rate so that the electric field generator continuously operates within the electric field limit” without undue burden. The phrase “letting the pressure increase” includes both direct (e.g. pumping additional gas into the reactor) and indirect measures (letting the gas/plasma heat up in the reactor by supplying power, thus increasing the pressure).

In an embodiment, the system comprises an input pump configured to pump reaction gas into the plasma reactor.

In an embodiment, the first pressure is between 0.01 mbar and 20 mbar, preferably between 0.05 mbar and 15 mbar, more preferably between 0.1 mbar and 10 mbar.

In an embodiment, the control unit is additionally configured to let the pressure in the plasma reactor increase at a rate such that a glow phase of the plasma lasts at most 2 seconds, preferably at most 1.5 seconds, more preferably at most 1 second.

In an embodiment, the letting the pressure in the plasma reactor increase comprises controlling the plasma power source to increase the electric field strength at a predetermined rate.

In an embodiment, the predetermined rate of increase of the electric field is at most 15 MV/m/s, preferably at most 10 MV/m/s.

In an embodiment, the pressure rate of increase is between 1 bar/s and 3 bar/s.

In an embodiment, the predetermined rate of increase of the electric field is chosen such that a current swing of the glow discharge does not exceed the stable glow discharge current.

In an embodiment, the system comprises a plasma state detection means connected to the controller. In an embodiment, said plasma state detection means comprises at least one of a current detecting means, a current and voltage detecting means, and a optical detecting means.

In an embodiment, the system comprises a pressure sensing means for sensing a pressure in the plasma reactor, said pressure sensing means connected to the controller.

The invention further provides a method for operating an atmospheric or super-atmospheric plasma, the method comprising:
lowering a pressure in a plasma reactor using a pump until a first pressure is reached;
subsequently or simultaneously using an electric field generator to apply an electric field in the plasma reactor until a plasma ignites in the plasma reactor;
after ignition, letting the pressure in the plasma reactor increase at a rate so that the electric field generator continuously operates within the electric field generation limit until a second pressure is reached;
operating the plasma at the second pressure.

In an embodiment, the letting the pressure in the plasma reactor increase comprises controlling the plasma power source to increase the electric field strength at a predetermined rate.

In an embodiment, the pressure rate of increase is between 1 bar/s and 3 bar/s.

The invention further provides a computer program product comprising instructions which, when executed on a controller, cause said controller to behave according to claim 1.

Further aspects and details of the invention will be disclosed in connection with the drawings and example embodiments described below.

### BRIEF DESCRIPTION OF THE FIGURES

Embodiments of the present invention will be described hereinafter, by way of example only, with reference to the accompanying drawings which are schematic in nature and therefore not necessarily drawn to scale. Furthermore, like reference signs in the drawings relate to like elements.

FIG. 1a schematically shows a piping and instrumentation diagram of a plasma operation system according the invention;

FIG. 1b schematically shows an alternative piping and instrumentation diagram of a plasma operation system according the invention;

FIG. 2a schematically shows an electrical diagram of a plasma operation system according the invention;

FIG. 2b schematically shows an alternative electrical diagram of a plasma operation system according the invention;

FIGS. 3a-c show breakdown voltage diagrams;

FIG. 4 shows a timing diagram for operating a plasma according the invention;

FIGS. 5a and 5b show voltage and current diagrams of, respectively, failed and successful glow-to-arc transitions;

FIGS. 6a and 6b show voltage and current diagrams of plasma ignitions using different high voltage slew rates; and

FIGS. 7a and 7b also show voltage and current diagrams of plasma ignitions using different high voltage slew rates.

Further variants will be described in the detailed description below.

### DETAILED DESCRIPTION

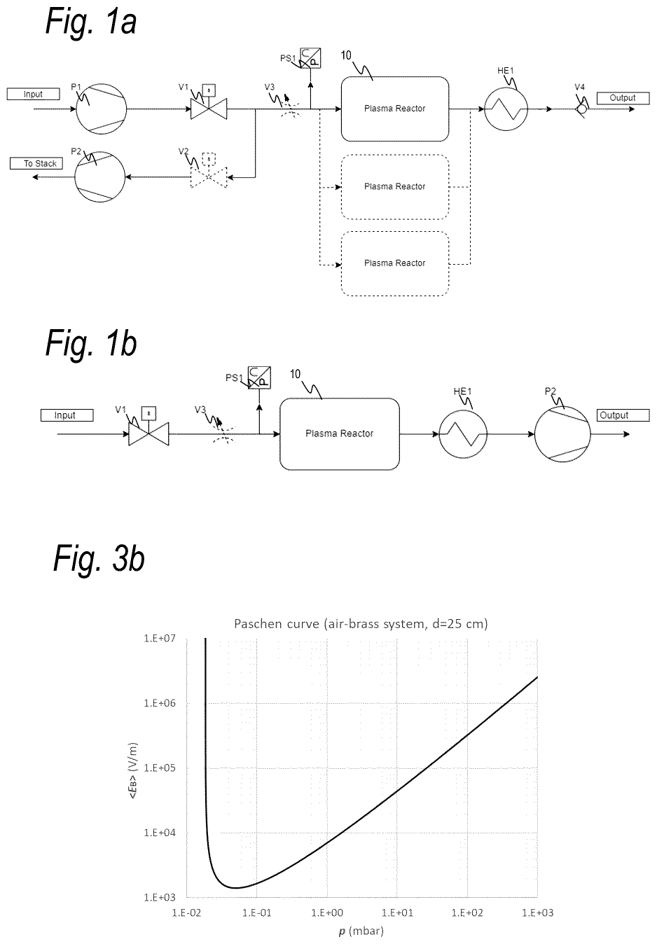

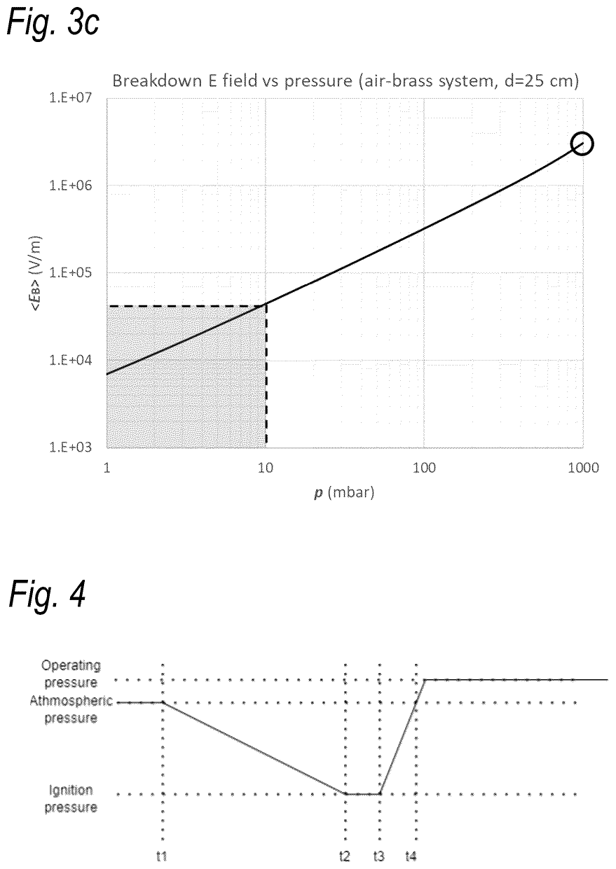

FIG. 1a schematically shows a piping and instrumentation diagram of a plasma operation system according the invention. In the following description, references to times t1, t2, t3, t4 will be made, as shown in the timing diagram of FIG. 4. Before startup, valve V1 is closed and valve V2 is opened, the system is at atmospheric pressure. Vacuum pump P2 is subsequently enabled (t1). Non return valve V4 will close and the air is the system can be extracted via P2. The pressure in the reactor can be monitored with pressure sensor PS1. P2 will be enabled until the desired vacuum level for ignition is reached (t2). V2 is closed and the plasma is subsequently started by enabling the high voltage power supply (t2-t3). V1 will now be opened to vent the plasma reactor 10 (t3-t4). Valve V3 is an optional (needle)valve to control the rate of rise of the pressure in the reactor to allow the glow-arc transition without the risk of quenching the plasma. Compressor P1 will subsequently be enabled to feed air through the reactor (t4). The hot gasses are cooled by the heat exchanger HE1 and exit the reactor the system via V4. V4 is placed behind the heat exchanger so the valve does not be able to handle high temperatures. The system is now in idle operation at a pressure which is typically above atmospheric pressure.

Multiple plasma reactors 10 can be used in parallel (shown in dotted lines in FIG. 1a).

There are many variations on how the valves at the input and output can be arranged. For instance:
V4 can also be a solenoid valve.
V4 can be placed directly after the reactor.
V2 can be omitted if the idle operating pressure is relatively low (e.g. <100 mbar), the vacuum pump will block this overpressure sufficiently
V1 & V2 can be combined in a 3/2-way valve.
V3 can be omitted if rate of pressure rise is not required.
V3 can be intrinsically in the system design by choosing certain pipe sizes or orifices in components.

In a typical system there will be one valve at the input and one valve at the output of the system. There will be a compressor which feeds gas in the system and a vacuum pump which extracts gas from the system.

FIG. 1b schematically shows an alternative piping and instrumentation diagram of a plasma operation system according the invention.

This more basic setup contains only one vacuum pump P2 at the output of the system and only one valve V1 at the input of the system. In this case the pump extracts gas from the system during starting (low pressure) and the pump sucks air through the system during idle operation (near atmospheric pressure). The system will then only be able to operate below atmospheric conditions. Again, multiple plasma reactors 10 can be used in parallel (not shown in FIG. 1b).

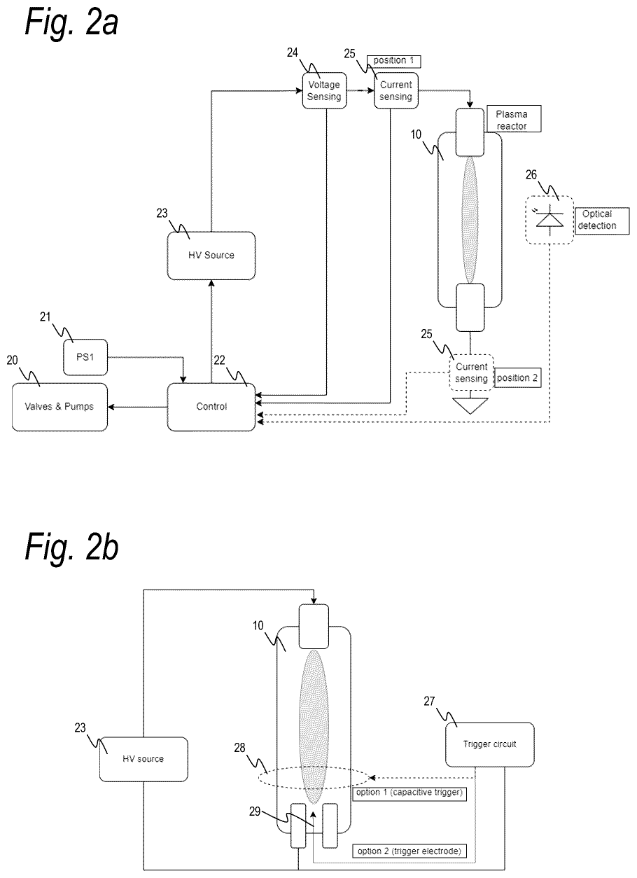

FIG. 2 schematically shows an electrical diagram of a plasma operation system according the invention.

The system consists of a high voltage (HV) source 23 (more generally: an electric field generator), one or multiple sensor(s) 26 for detecting if the plasma is ignited and a control system 22 with connected Power Stage 1 module 21. Voltage and current sensing devices 24, 25 provide operational data, which could also be used for detecting if the plasma is ignited. The valves and pumps 20 have been described in reference to FIGS. 1a and 1b. Even though only one plasma reactor 10 is shown, multiple such plasma reactors can be used with one HV source.

The high voltage source 23 can be a AC or DC source, for example delivering 0.5-30 kV (typically 5 kV) at 50 Hz-1 MHz (typically 100 kHz). An example high voltage is able to operate in two regimes: high voltage (typically 10-30 kV) for ignition of the plasma, and a lower voltage with a low output impedance to drive the arc plasma during idle operation (typically 1-10 kV).

The control circuit 22 controls the high voltage source, valves and pumps and timing of all events during starting of the plasma. The system should be able to detect if the plasma is ignited. There are multiple ways to detect the state of the plasma (off state, glow state or arc state).

Detection by current at any position in the circuit: Multiple options for the current sensor can be applied e.g. shunt resistor, rogowski coil, current sense transformer or hall-effect sensor. There are multiple positions for current sensing possible. For instance: 1) Measure the current through the reactor. “No” current=plasma off (a small capacitive current can be present in the off state), above certain threshold (e.g. >100 mA)=ignited. Position of the current sensor can be at the high voltage side or at the grounded side of the reactor. 2) Measure currents in the internal circuitry of the HV/Plasma Source. 3) Measure the supply current of the HV/Plasma Source.

Detection by current and voltage at any position in the circuit: This is similar to current detection, but with the additional benefit that measuring the current and voltage will give full insight in the VI-characteristic and power of the plasma. Plasma off, glow and arc regime can be distinguished.

Optical detection: Presence of plasma in the reactor can be detected by an optical sensor (e.g photo diode, LDR, CCD, etc.) Intensity of the signal can be used to distinguish to plasma off, glow and arc state.

Detection by pressure or flow behavior: Presence of plasma in the reactor changes pressure drop and gas flow haviour in the reactor. Ignition moment itself can be detected by a momentaneous pressure peak.

An alternative way of igniting the plasma if the OCV of the source is not sufficient is to implement an additional trigger electrode and trigger source, as shown in FIG. 2b.

A ring electrode 28 is placed around (or other shaped electrode is placed near) the wall of the glass/quartz reactor tube 10, positioned near one of the reactor electrodes. The high voltage (1-10 kV) trigger pulse from trigger circuit 27 (which may be connected to the HV source 23) disturbs the E field near the electrode generating electrodes which promote the full discharge in the reactor. The generated E field can be strong enough to create discharges inside the reactor at the electrode which initiates the full discharge.

Additionally or alternatively, a trigger electrode 29 is added in or near one on the electrodes (top or bottom) of the plasma reactor. A small discharge can be created by an external trigger circuit 27 (1-10 kV) which initiates the full discharge in the reactor.

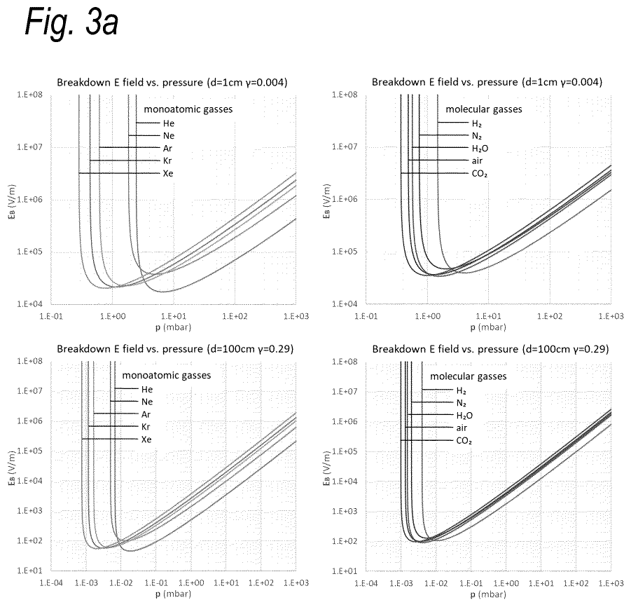

FIGS. 3a-c show breakdown voltage diagrams.

The voltage or electric field required to ignite a plasma device is typically higher than its operating voltage or electric field. The difference between those electric fields usually increases at higher fill pressures. The required voltage also increases at longer electrode distances, which poses a technological challenge as the power supply has to deliver a higher open-circuit voltage and the circuit connecting it to the plasma device has to be designed to withstand the electrical stress. Both factors result in a more complex system, which has a negative impact on both cost and reliability. It is therefore the goal of the present invention to solve that problem by lowering the ignition electric field or voltage requirement of the plasma reactor.

The breakdown voltage V_{B} can be decreased significantly by reducing the gas fill pressure inside the reactor. Decreasing the gas density between the electrodes allows the development of an electron avalanche at a lower applied electric field. At pressures below 100 mbar this process is best described by the Townsend mechanism of the electrical breakdown, from which Paschen's law is derived. This equation, given below, provides the relation between the plasma reactor's design parameters (electrode material, gas fill pressure, and nature of gas) and its ignition voltage V_{B} (in [V]), assuming a homogeneous electric field between a pair of cold electrodes:

$${V}_{B} = \frac{B \cdot pd}{ln ( A \cdot pd ) - ln ( ln ( 1 + \frac{1}{γ} ) )} , \qquad ( 1 )$$

In this equation, p is the pressure in [mbar], d is the inter-electrode distance in [m], γ is the secondary electron emission coefficient (number of electrons released per impinging ion), A is the saturation ionization in the gas (in [mbar⁻¹ m⁻¹]) and B is a constant related to the excitation and ionization energies of the elements composing the gaseous atmosphere (expressed in [V mbar⁻¹ m⁻¹]).

Assuming a constant γ parameter, Paschen's formula can then be reduced to the following simplified expression:

$$\frac{{V}_{B}}{{V}_{Bmin}} = \frac{pd / {pd}_{m i n}}{1 + ln ( pd / {pd}_{m i n} )} , \qquad ( 2 )$$

where pdₘᵢₙ and V_{Bmin} are the pressure-distance product and the breakdown voltage at the Stoletow point (minimum) of the Paschen curve, respectively. Those parameters have the following expressions:

$${V}_{Bmin} = \overline{e} \frac{B}{A} ln ( 1 + \frac{1}{γ} ) \qquad ( 3 )$$

$${pd}_{m i n} = \frac{\overline{e}}{A} ln ( 1 + \frac{1}{γ} ) , \qquad ( 4 )$$

where ē is Euler's number, i.e., ē=exp(1)=2.718.

We find that when considering the fixed geometry of a given plasma device and expressing the breakdown requirement in terms of electric field, equation (2) then becomes:

$${E}_{B} ( p ) = {E}_{Bmin} \cdot \frac{p / {p}_{m i n}}{1 + ln ( p / {p}_{m i n} )} , \qquad ( 5 )$$

where pₘᵢₙ and E_{Bmin} are the pressure and the minimum breakdown electric field at the Stoletow point, respectively. The expressions of those parameters can be calculated from (3) and (4):

Equation (5) is a generalized expression of Paschen's law which is applicable to standard plasma devices provided with electrodes as well as electrodeless devices, i.e., capacitively or inductively coupled plasma systems. In this context γ is a property of the plasma system's inner walls or electrodes, depending on the nature of E-field coupling, and d is now the characteristic dimension of the system's vessel in the direction of the applied electric field.

The lowest pressure pₗᵢₘ at which point the breakdown E field tends towards infinity (Hittorf effect, by extension from (2)) can be calculated from the following condition 1+In(pₗᵢₘ/pₘᵢₙ)=0, resulting in the definition:

$${p}_{li m} = \frac{{p}_{m i n}}{\overline{e}} = \frac{1}{dA} ln ( 1 + \frac{1}{γ} ) \qquad ( 6 )$$

When the applied electric field is not homogeneous, formula (5) is approximated by the following expression:

$$〈 {E}_{B} ( p ) 〉 = 〈 {E}_{Bmin} 〉 \cdot \frac{p / {p}_{m i n}}{1 + ln ( p / {p}_{m i n} )} , \qquad ( 7 )$$

where [symbol] E_{B}(p) [symbol] and [symbol] E_{Bmin} [symbol] are spatially-averaged parameters (expressions (3) and (4) still apply).

All equations provided here describe the fundamental ignition behaviour of plasma devices and depend on the system's design parameters that are characterized by the d, A, B, and γ coefficients.

The d, A, B, and γ coefficients that determine the plasma system's electrical breakdown properties depend directly on the system's design. Those parameters vary greatly depending on the nature of the gas fill and the walls/electrodes. Data from the literature shows that for typical gases (i.e., noble and molecular gases) A ranges from 2.25·10⁵ to 1.95·10⁶ bar⁻¹ m⁻¹ and B ranges from 2.550·b 10⁶ to 3.495·10⁷ V bar⁻¹ m⁻¹, whereas γ ranges typically from 0.004 to 0.29 for usual electrode/wall materials.

This variability, plus that of the plasma system's dimensions, results in a very wide range of possible plasma breakdown characteristics, shown in FIG. 3a, calculated for a number of usual gases used in plasma systems and for two typical γ and d values.

It is clear from the diagrams shown in FIG. 3a that the breakdown E-field varies nearly linearly with pressure in the p>pₘᵢₙ range, meaning that reducing the pressure by a certain factor will lower the breakdown voltage and electric field by a similar factor.

The range of pressure meeting the condition for the reduced breakdown E-field depends primarily on the design of the plasma device (gas filling, dimensions and nature of walls/electrodes). Advantageously, given e.g. a desired breakdown electric field strength, it is possible to determine what the corresponding pressure is (if it exists on the E-p curve). By lowering the pressure to the calculated pressure level, the plasma can be ignited at the desired electric field strength.

According to an embodiment, in order to ignite atmospheric- and super-atmospheric-pressure plasma reactors the pressure is reduced temporarily below a certain level in order to allow the development of ionization at an applied voltage level close to or lower than the reactor's operating voltage

According to an embodiment, the degree of reduction in pressure to ignite the plasma system matches or is similar to the degree of desired reduction in breakdown voltage or electric field.

According to an embodiment, the pressure p during the starting phase is in the pₗᵢₘ<p<pₒₚ range. According to an embodiment, the pressure p during the starting phase is at least in the pₘᵢₙ≤p<pₒₚ range, with pₒₚ the operational pressure of the system, and pₘᵢₙ and pₗᵢₘ are defined in (4) and (6).

The invention can also be applied to systems whose dimensions or geometry result in a plasma breakdown that is affected by the diffusional loss of charges to the wall as this process typically offsets the Paschen curve towards higher voltage and higher pd values which, by extension from (1), applies to (5) as well in the (E_{B},p) domain (i.e., the shift is towards higher pressures and electric fields). That situation is typically found in plasma devices with an aspect ratio much different than unity, such as discharge tubes whose length is much greater than the diameter.

Likewise, the use of ignition aids, such as UV irradiation and E-field enhancement, do not change the applicability of the invention as those measures do not affect the limit (7) due to the fundamental nature of the Hittorf effect (although “vacuum” ignition is possible at very low pressures, below the Hittorf limit (7), but it requires extremely high electric fields). For this reason, the invention can also be applied to all frequencies typically used in plasma power sources, including DC.

Table 1 below provides the value of key parameters within the typical d and γ ranges, with the left numbers corresponding to d=100 cm and γ=0.29 whereas the right ones are for d=1 cm and γ=0.004.

TABLE 1

| gas | Pₗᵢₘ (mbar) | Pₘᵢₙ (mbar) | gas | Pₗᵢₘ (mbar) | Pₘᵢₙ (mbar) |
|---|---|---|---|---|---|
| He | 6.63E−03-2.46E+00 | 1.80E−02-6.68E+00 | H₂ | 3.98E−03-1.47E+00 | 1.08E−02-4.01E+00 |
| Ne | 4.98E−03-1.84E+00 | 1.35E−02-5.01E+00 | N₂ | 1.99E−03-7.37E−01 | 5.41E−03-2.00E+00 |
| Ar | 1.66E−03-6.14E−01 | 4.51E−03-1.67E+00 | CO₂ | 9.95E−04-3.68E−01 | 2.70E−03-1.00E+00 |
| Kr | 1.17E−03-4.33E−01 | 3.18E−03-1.18E+00 | H₂O | 1.53E−03-5.67E−01 | 4.16E−03-1.54E+00 |
| Xe | 7.65E−04-2.83E−01 | 2.08E−03-7.70E−01 | air | 1.33E−03-4.91E−01 | 3.61E−03-1.34E+00 |

Data shows that pressure in larger plasma systems built with high-γ materials can be lowered to very low pressures in order to reach ignition conditions, typically between 0.765 and 6.63 μbar. Smaller systems with low-γ electrodes or walls are characterized by a significantly higher pressure at the Hittorf limit, i.e., between 0.283 and 2.46 mbar.

Table 2 below provides the ratio between the breakdown E field strength at 1 bar and that at the Stoletow point. These data provide an estimate over the typical d and γ ranges of the potential reduction in breakdown E field requirement that is achievable when reducing pressure down to pₘᵢₙ for a plasma system normally operating at atmospheric conditions (approximately). The left numbers in the range correspond to d=1 cm and γ=0.004, whereas the ones on the right are for d=100 cm and γ=0.29.

TABLE 2

| gas | $\frac{{E}_{B 1 bar}}{{E}_{Bmin}}$ | gas | $\frac{{E}_{B 1 bar}}{{E}_{Bmin}}$ |
|---|---|---|---|
| He | 2.49E+01 − 4.65E+03 | H₂ | 3.83E+01 − 7.43E+03 |
| Ne | 3.17E+01 − 6.06E+03 | N₂ | 6.92E+01 − 1.41E+04 |
| Ar | 8.10E+01 − 1.67E+04 | CO₂ | 1.26E+02 − 2.68E+04 |
| Kr | 1.10E+02 − 2.30E+04 | H₂O | 8.68E+01 − 1.79E+04 |
| Xe | 1.59E+02 − 3.41E+04 | air | 9.83E+01 − 2.05E+04 |

Data show that the maximum potential reduction in breakdown E field by reducing pressure is limited to a factor 24.9-159 in small plasma systems with electrodes or walls that have a low-γ value. Large plasma systems built with high γ materials have a much greater potential reduction in breakdown E field, i.e., a factor typically between 4650 and 34100.

In an embodiment, for small (centimeter-sized) plasma systems, pressure can be lowered down to 0.765 μbar in order to reach ignition conditions, with a reduction factor of the (averaged) breakdown E field compared to atmospheric conditions reaching up to 159.

In another embodiment, for large (decimeter-sized) plasma systems, pressure can be lowered down to 0.283 mbar in order to reach ignition conditions, with a reduction factor of the (averaged) breakdown E field compared to atmospheric conditions reaching up to 34100.

Considering a tubular air-plasma reactor with an electrode gap length of 25 cm operating at atmospheric pressure, the typical operating voltage can reach up to 10 kV, corresponding to an maximum average operational electric field of 4.0·10⁴ V m⁻¹.

The requirement for the system's ignition is thus set for a breakdown E field not exceeding that value.

The pressure that is required to meet this condition is estimated via the application of the generalized Paschen law (7), using A, B, and γ coefficients relative to dry air and to the desired electrode material. Because of the highly reactive nature of air plasmas, reactors filled with this gas are usually provided with electrodes made of brass or stainless steel. For brass, using the following parameters
A=11.25 mbar⁻¹ cm⁻¹, B=273.75 V mbar⁻¹ cm⁻¹, and γ=0.0053 result in the breakdown E field characteristic shown in FIG. 3b.

A typical atmospheric air plasma reactor has an electrode gap length of d=250 mm. Assuming the applicability of a homogeneous electric field (Townsend mechanism of the electrical breakdown), the breakdown vs. pressure characteristic for such a reactor can be obtained from results from Paschen's law, and is shown in FIG. 3c. Key breakdown parameters calculated for this case are: pₗᵢₘ=18.7 μbar, pₘᵢₙ=50.7 μbar, and E_{Bmin}=1387.8 V/m. The maximum factor by which the breakdown E field can be reduced via pressure reduction in this system is E_{B1bar}/E_{Bmin}=1811.4.

It is found that the ignition condition defined earlier (i.e., maximum breakdown E field not exceeding 4.0·10⁴ V m⁻¹) is met at a pressure of 10 mbar and lower, which was confirmed experimentally using a pump that could lower pressure down to 0.1 mbar. The required ignition condition is indicated by the shaded area on the left in FIG. 3c, with the circle on the right identifying the ignition E field required around the operating pressure of the system.

In FIG. 3c, data at pressures beyond 100 mbar were corrected for the different mode of plasma ignition (i.e., onset of streamers). The corresponding numerical values of the breakdown voltage are given for various pressure levels in table 3.

TABLE 3

| Pressure | breakdown E |
|---|---|
| (mbar) | field (V/m) |
| 1000 | 3.017 · 10⁶ |
| 400 | 1.133 · 10⁶ |
| 100 | 3.194 · 10⁵ |
| 40 | 1.427 · 10⁵ |
| 10 | 4.356 · 10⁴ |
| 4 | 2.040 · 10⁴ |

The data shows that reducing the pressure by a factor hundred (i.e., from 1000 to 10 mbar) enables a reduction of the averaged breakdown E field by a factor 69.3, which is reflected in the measured breakdown voltage of the plasma device (ca. 10 kV vs. an estimated 750 kV at atmospheric conditions)

In an embodiment, the system pressure is reduced by a factor hundred in order to lower the breakdown electric field.

In an embodiment, the pressure reduction reaches a level of 10 mbar or lower to allow a breakdown electric field at least a 65 times lower than that at atmospheric pressure (or 1000 mbar).

While the reduced pressure atmosphere allows a significantly reduced ignition voltage, the normal or abnormal glow discharge that develops after breakdown subjects the cathode to heavy ion bombardment that results in sputtering. It is therefore important that the pressure is not reduced below 0.1-1.0 mbar and that the duration of the glow phase should be kept as short as possible (<30 s). Limiting the minimum pressure level also advantageously allows the use of simple vacuum pumps.

In an embodiment, the minimum pressure should be higher than 0.1-1.0 mbar, e.g. to limit material evaporation, sputtering and other surface damages from ion bombardments

In an embodiment, the plasma glow phase (or low-pressure phase) after ignition should not last more than 5, 10, 15, 20 or 30 seconds, e.g. to limit material evaporation, sputtering and other surface damages from ion bombardments.

FIG. 4 shows a timing diagram for operating a plasma according the invention.

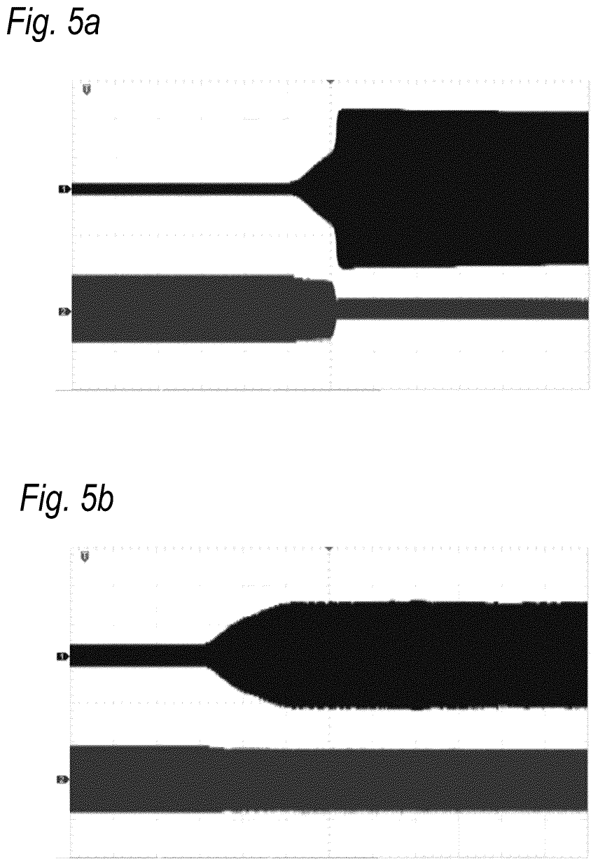

FIGS. 5a and 5b show voltage and current diagrams of, respectively, failed and successful glow-to-arc transitions.

The transition from a low-pressure diffuse glow discharge to a high-pressure arc (or) filamentary plasma causes the voltage drop across the electrodes to rise significantly. A key condition to ensure a successful transition is that the changing voltage during the pressurization phase never exceeds the PSU's OCV. The rate of pressure increase is also an important factor as this affect the rate of voltage change (i.e., perturbation of the electrode and plasma operations depend on the rate of gas density increase).

The oscillographs of FIGS. 5a and 5b show the measured voltage (ch1) and current (ch2) wave envelopes during the glow-to-arc transition during the pressurization phase from 5 mb to one atmosphere. In both cases power is delivered by a constant-current resonant power supply operating at 37 kHz. The reactor is built with a 40-mm-diameter quartz tube vessel provided with aluminum electrodes with a 195-mm gap length.

FIG. 5a shows a failed glow-to-arc transition via pressure increase from 5 mbar to atmospheric within 0.2 s, 10 kV/div and 50 mA/div, 200 ms/div time constant. In this case the rate of pressure increase was too great (5 bar/s) and caused the plasma to extinguish; the current drops to capacitive level while the voltage rise to the PSU's OCV at 1.24 s.

FIG. 5b shows a successful glow-to-arc transition via pressure increase from 5 mbar to atmospheric within 0.5 s, 5.0 kV/div and 50 mA/div, 200 ms/div time constant. In this case, the rate of pressure increase was lowered to 2 bar/s which allows a successful transition (current practically constant and voltage never reached of exceeded the PSU's OCV).

In an embodiment, the maximum rate of pressure change is 2 bar per second. In an embodiment, the rate of pressure change is limited in such a way that the voltage across the plasma reactor terminal never exceeds the power supply's open circuit voltage, defined as a value close to the reactor's nominal operating voltage.

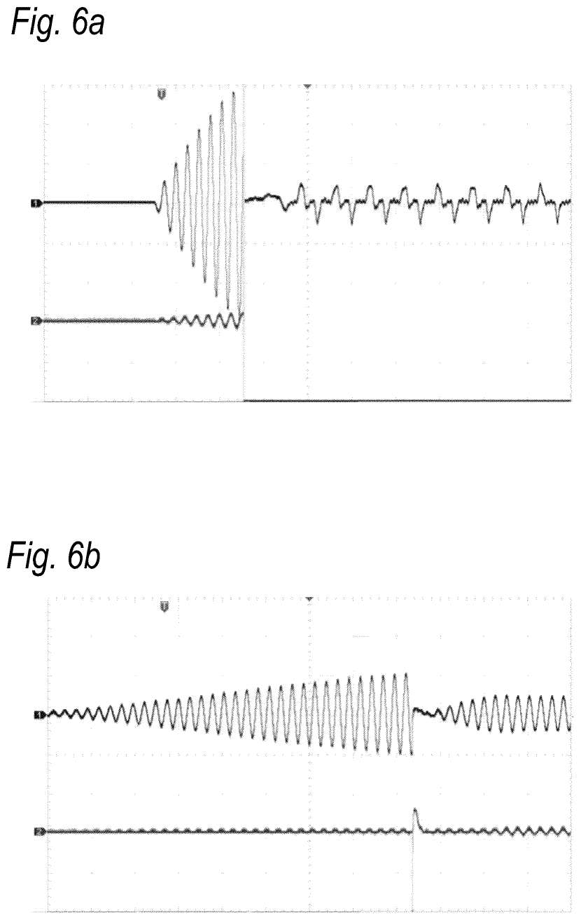

FIGS. 6a and 6b show voltage and current diagrams of plasma ignitions using different high voltage slew rates.

Power supplies can have a resonant LC tank in their output stage. These power supplies are known to have an output voltage that increases from the moment the oscillator is powered on. The rate of voltage rise per second (slew rate) depends on the oscillator's Q factor and is always fastest before plasma ignition as no conduction current is drawn from the LC circuit by the reactor. This characteristic, combined with the ignition lag time of the reactor, caused by the statistical delay of primary electron appearance in the gas volume between the electrodes, can cause the applied voltage to rise well above the static ignition voltage level, thus limiting the benefits of lowering the pressure.

The oscillographs shown in FIGS. 6a and 6b show the measured current (ch1) and voltage (ch2) waveforms during ignition in air at around 5 mbar for two different applied voltage slew rates. The applied voltage has a frequency of 37 kHz in both cases. The reactor is built with a 40-mm-diameter quartz tube vessel provided with aluminum electrodes with a 195-mm gap length.

FIG. 6a shows ignition at high voltage slew rate (1.5 GV/s), 10 kV/div and 100 mA/div, 100 μs/div time base. Electrical breakdown occurs at 30 kVₚₑₐₖ. Note that the current waveform is off scale after ignition.

FIG. 6b shows ignition at high voltage slew rate (6.2 MV/s), 5.0 kV/div and 100 mA/div, 100 μs/div time base. Electrical breakdown occurs at 5 kVₚₑₐₖ.

In the first case, the resonant PSU has a fast slew rate of 1.5 GV/s, causing the peak voltage before electrical breakdowns to reach 30 kV. Reducing that slew rate to 6.2 MV/s (second case) increases the statistical delay of ignition from 200 to 830 μs but the maximum voltage peak before breakdown is reduced six-fold to 5 kV only.

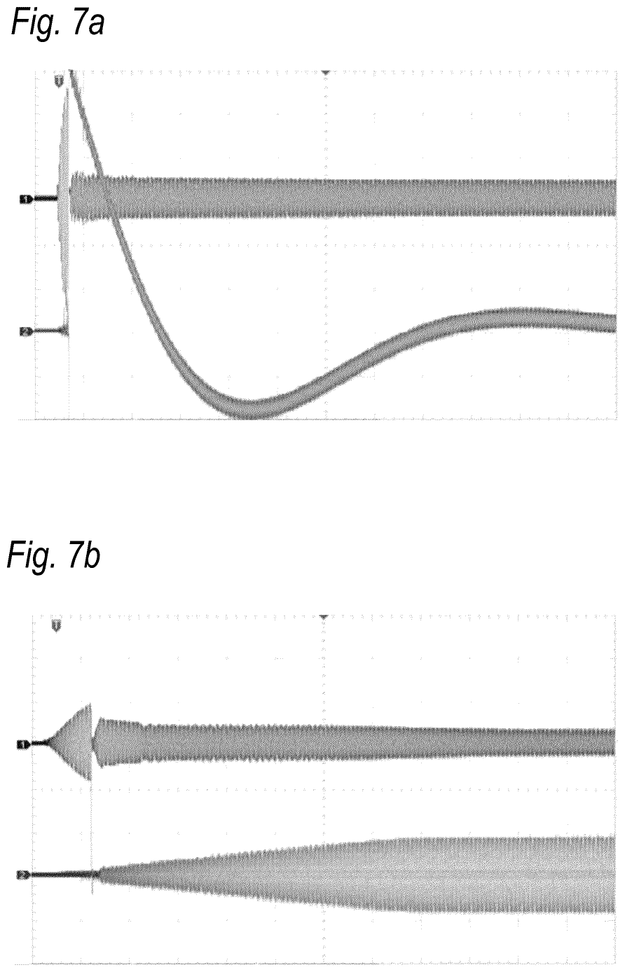

FIGS. 7a and 7b also show voltage and current diagrams of plasma ignitions using different high voltage slew rates.

The way the glow discharge develops after ignition is also affected by the voltage slew rate. The oscillographs of FIGS. 7a and 7b show the evolution of the glow current waveforms (ch 2) after ignition for the two different slew rates.

FIG. 7a shows onset of a glow discharge after a high voltage slew rate ignition (1.5 GV/s), 10 kV/div and 200 mA/div, 1.0 ms/div time base. FIG. 7b shows onset of glow discharge after a low voltage slew rate ignition (3.6 MV/s), 5.0 kV/div and 50 mA/div, 1.0 ms/div time base.

Ignition at high voltage slew rate (FIG. 7a) causes a large current swing (+1.2 A to −400 mA) as a result of the sudden closing of the circuit while a large amount of energy is stored in the PSU's LC tank. This current swing is significantly larger than the stable glow discharge current (45 mA peak), which is bound to cause electrode damages (enhanced sputtering and of other deleterious plasma-surface processes) as well as stressing components in the PSU and in the circuit connecting it to the reactor.

In contrast, the ignition at low voltage slew rate (FIG. 7b) results in a much smoother establishment of the glow discharge, with a current free of wide swings. The formative time of the glow is 7 ms in this case, about twice as long as for the starting condition with fast voltage slew rate (3.4 ms).

In an embodiment, in order to limit current and voltage stresses to electrodes and electrical components, the maximum voltage slew rate does not exceed 10 MV/s when resonant power supplies are used.

In an embodiment, the energy stored in the power supply's output stage (LC tank for AC systems and C in DC systems) at the moment of plasma ignition is limited in such a way that the transient currents do not exceed a certain level (preferably the normal operating current).

In the foregoing description of the figures, the invention has been described with reference to specific embodiments thereof. It will, however, be evident that various modifications and changes may be made thereto without departing from the scope of the invention as summarized in the attached claims.

In addition, many modifications may be made to adapt a particular situation or material to the teachings of the invention without departing from the essential scope thereof. Therefore, it is intended that the invention not be limited to the particular embodiments disclosed, but that the invention will include all embodiments falling within the scope of the appended claims.

In particular, combinations of specific features of various aspects of the invention may be made. An aspect of the invention may be further advantageously enhanced by adding a feature that was described in relation to another aspect of the invention.

It is to be understood that the invention is limited by the annexed claims and its technical equivalents only. In this document and in its claims, the verb “to comprise” and its conjugations are used in their non-limiting sense to mean that items following the word are included, without excluding items not specifically mentioned. In addition, reference to an element by the indefinite article “a” or “an” does not exclude the possibility that more than one of the element is present, unless the context clearly requires that there be one and only one of the elements. The indefinite article “a” or “an” thus usually means “at least one”.

1. A system for operating an atmospheric or super-atmospheric plasma, the system comprising:
a plasma reactor
an electric field generator configured to generate an electric field in the plasma reactor, said electric field generator having an electric field generation limit;
characterized by:
a pump configured to remove gas from the plasma reactor;
a control unit;
wherein the control unit is configured to
lower the pressure in the plasma reactor using the pump until a first pressure is reached;
subsequently or simultaneously applying the electric field in the plasma reactor until a plasma ignites in the plasma reactor;
after ignition, letting the pressure in the plasma reactor increase at a rate so that the electric field generator continuously operates within the electric field generation limit until a second pressure is reached;
operating the plasma at the second pressure.

2. The system of claim 1, further comprising an input pump configured to pump reaction gas into the plasma reactor.

3. The system of claim 1, wherein the first pressure is between 0.01 mbar and 20 mbar.

4. The system of claim 1, wherein control unit is additionally configured to let the pressure in the plasma reactor increase at a rate such that aglow phase of the plasma lasts at most 2 seconds.

5. The system of claim 1, wherein the letting the pressure in the plasma reactor increase comprises controlling the electric field generator to increase the electric field strength at a predetermined rate.

6. The system of claim 5, wherein the predetermined rate of increase of the electric field is at most 15 MV/m/s.

7. The system of claim 1, wherein the pressure rate of increase is between 1 bar/s and 3 bar/s.

8. The system of claim 5, wherein the predetermined rate of increase of the electric field is chosen such that a current swing of the glow discharge does not exceed a stable glow discharge current.

9. The system of claim 1, comprising a plasma state detection means connected to the controller.

10. The system according to claim 9, wherein said plasma state detection means comprises at least one of a current detecting means, a current and voltage detecting means, and a optical detecting means.

11. The system according to claim 1, comprising a pressure sensing means for sensing a pressure in the plasma reactor, said pressure sensing means connected to the controller.

12. A method for operating an atmospheric or super-atmospheric plasma, the method comprising:
lowering a pressure in a plasma reactor using a pump until a first pressure is reached;
subsequently or simultaneously using an electric field generator to apply an electric field in the plasma reactor until a plasma ignites in the plasma reactor, said electric field generator having an electric field generation limit;
after ignition, letting the pressure in the plasma reactor increase at a rate so that the electric field generator continuously operates within the electric field generation limit until a second pressure is reached;
operating the plasma at the second pressure.

13. The method of claim 12, wherein the letting the pressure in the plasma reactor increase comprises controlling the electric field generator to increase the electric field strength at a predetermined rate.

14. The method of claim 12, wherein the pressure rate of increase is between 1 bar/s and 3 bar/s.

15. A method for operating a super-atmospheric plasma, the method comprising:
using an electric field generator to apply an electric field in the plasma reactor until a plasma ignites in the plasma reactor;
after ignition, letting the pressure in the plasma reactor increase at a rate so that the electric field generator continuously operates within an electric field limit until a second pressure is reached;
operating the plasma at the second pressure.

16. (canceled)
